(19) United States
(12) Patent Application Publication
(10) Pub. No.: US 2007/0169700 A1
(43) Pub. Date: Jul. 26, 2007

(54) Sensing system and method for determining the alignment of a substrate holder in a batch reactor

(76) Inventors: Gert-Jan Sniders, Arnorsfort (NL); Bartholomeus H.L. Lindeboom, Bilthoven (NL)

Correspondence Address: KNOBBE MARTENS OLSON & BEAR LLP, 2040 MAIN STREET, FOURTEENTH FLOOR, IRVINE, CA, 92614, US

(21) Appl. No.: 11/341,087

(22) Filed: Jan. 26, 2006

(51) Int. Cl. H01L 21/306; C23C 16/00

(52) U.S. Cl. 118/724; 118/715; 156/345.51; 156/912; 156/345.24; 118/728

(57) ABSTRACT

A remotely-controlled sensing system is used to measure the alignment of a substrate holder, such as a wafer boat, in a batch reactor, such as a furnace, for processing semiconductor substrates. The sensing system is loaded into a slot in the substrate holder and the substrate holder is loaded into a process chamber of the reactor, to allow measurements to be taken while the substrate holder is sealed inside the reactor. The sensing system includes a transceiver to communicate with a controller and a data collection unit outside the process chamber. The sensing system also includes a distance sensor to measure the distance from the sensor to the wall of the process chamber. The sensor is rotated to obtain measurements over a 360° sweep of the process chamber. The alignment of the substrate holder in the process chamber is determined based upon the relationship between the angle of rotation and the measured distance or the signal received by the distance sensor.

### BACKGROUND OF THE INVENTION

1. Field of the Invention

This invention relates generally to reactors for semiconductor substrate processing and, more particularly, to batch reactors.

2. Description of the Related Art

Semiconductor substrates can be processed in batches in reactors such as vertical furnaces. An example of such processing is the deposition of films on the substrates. For a variety of reasons, including uniformity of electrical and physical properties, high purity and uniformity is typically desired for the deposited films. Deposition results, however, can be adversely affected by non-uniformities in gas flow patterns. For example, non-uniform gas flow patterns can result in non-uniform reactant concentrations inside the furnace, which can cause films to be deposited at non-uniform rates, thereby resulting in non-uniform deposited films. Similar non-uniformities can result for other processes, such as oxidation or doping.

Wafer boats can be used to hold the substrates during processing in the furnace. For example, a plurality of wafers can be held in a vertically stacked and spaced relationship on the boats. The wafer boat can be accommodated in a process tube in the furnace. The process tube defines a process chamber in the furnace.

Gas flow patterns can be affected by the alignment of wafer boats in the furnace. A wafer boat that is not centered correctly with respect to the cylindrical process tube can cause a non-uniform gas flow pattern and non-uniform process results.

The non-uniform gas flow patterns can occur in various situations. For example, a non-uniform flow pattern can occur where O₂ is fed into the process tube at a top end of the tube and is exhausted from a bottom end of the tube, with a bottom part of the tube purged with N₂. Because N₂ is lighter than O₂, the N₂ has a tendency to rise into the process tube. This rising of the N₂ is uncontrolled and non-uniform, particularly if the wafer boat is not aligned centrally in the process tube. If the N₂ rises up to the area where the wafers are located, it will influence the process results detrimentally by non-uniformly diluting the O₂. However, even without dilution by the N₂ purging gas, an improperly aligned wafer boat can cause a non-uniform gas flow pattern, which can cause non-uniform process results.

A difficulty with correcting wafer boat misalignments, however, is that the alignment is most accurately measured when the wafer boat is inside the process tube, preferably with the tube in the fully closed position just as it is during processing. Undesirably, a wafer boat in such a location is typically not accessible for measurement. Accordingly, there is a need for systems and methods to measure the alignment of a wafer boat in a process tube when the process tube is closed.

### SUMMARY OF THE INVENTION

According to one aspect of the invention, a semiconductor processing system is provided. The system comprises a vertical batch furnace having a process chamber, a wafer boat and a distance measurement system. The wafer boat is configured to be accommodated in the process chamber and comprises a plurality of wafer slots for accommodating semiconductor wafers. The distance measurement system comprises a base plate sized and shaped to be accommodated in a wafer accommodation. The distance measurement system also comprises a distance sensor attached to the base plate.

According to another aspect of the invention, a sensor system is provided for measuring the alignment of a substrate holder in a process chamber of a semiconductor processing batch reactor. The sensor system comprises a sensor base configured to mount on the substrate holder and a distance sensor rotatably mounted to the sensor base. The distance sensor is configured to sense a signal indicative of distance between the sensor and a wall of the process chamber. The sensor system also comprises a motor configured to rotate the sensor.

According to yet another aspect of the invention, a sensor system is provided for determining the alignment of a substrate holder in a semiconductor batch process chamber. The sensor system comprises a base plate sized and shaped to be accommodated in a substrate accommodation of the substrate holder. The sensor system also comprises a distance sensor mounted to the base plate.

According to another aspect of the invention, a method is provided for measuring the alignment of a wafer boat in a vertical semiconductor processing furnace. The method comprises loading the wafer boat into a process chamber of the vertical furnace. A distance sensing device is accommodated on the wafer boat. The distance sensing device is rotated inside the process chamber. A signal indicated of the distance between the distance sensing device and a wall of the process chamber is sensed by the sensing device.

According to another aspect of the invention, a method is provided for determining alignment of a semiconductor substrate holder in a process chamber of a batch reactor. The method comprises providing the substrate holder, which has a plurality of substrate accommodations. The substrate holder is loaded into the process chamber. An alignment of a substrate holder axis relative to a wall of the process chamber is determined. The substrate holder axis extends vertically and substantially through a center of the substrate holder. An alignment, relative to the wall, of a substrate holder rotation axis on which the substrate holder rotates is separately determined.

According to yet another aspect of the invention, a method is provided for measuring alignment of a wafer boat in a batch process chamber. The method comprises providing the wafer boat having a plurality of wafer accommodations. An alignment measurement sensor is loaded into at least one of the wafer accommodations. The wafer boat with the alignment measurement sensor is loaded into the process chamber.

According to another aspect of the invention, a sensor system is provided for measuring the alignment of a substrate holder in a process chamber of a semiconductor processing batch reactor. The sensor system comprises a sensor base configured to mount on the substrate holder. The sensor system further comprises at least one distance sensor mounted to the sensor base. The distance sensor is configured to sense a signal indicative of distance between a wall of the process chamber and the sensor. The sensor system is configured to sense the signal indicative of distance in at least three different directions, the directions distributed in a plane.

### BRIEF DESCRIPTION OF THE DRAWINGS

The invention will be better understood from the detailed description of the preferred embodiments and from the appended drawings, which are meant to illustrate and not to limit the invention and wherein like numerals refer to like parts throughout.

FIG. 1 shows a vertical furnace with a wafer boat accommodated inside a process tube, in accordance with preferred embodiments of the invention;

FIG. 2A is a schematic top view of a measuring station positioned in a wafer boat in a furnace, in accordance with preferred embodiments of the invention;

FIG. 2B is a schematic side view of the measuring station, wafer boat and furnace of FIG. 2, in accordance with preferred embodiments of the invention;

FIG. 3 shows, schematically, output signals for a wafer boat that is substantially centered and a wafer boat that is off center, in accordance with preferred embodiments of the invention;

FIG. 4 shows the use of the triangulation principle to determine distance using radiation emitted from a sensor, in accordance with preferred embodiments of the invention;

FIG. 5 shows distance data measured with an ultrasound distance sensor, in accordance with preferred embodiments of the invention;

FIGS. 6A and 6B schematically illustrate the relationship of various variables used to determine the alignment of a wafer boat in a process tube, in accordance with preferred embodiments of the invention; and

FIGS. 7A-7F schematically illustrate various possible alignments of a wafer boat in a process tube, in accordance with preferred embodiments of the invention.

FIG. 8 is a schematic top view of a sensor system positioned in a wafer boat in a furnace having multiple sensors oriented in different directions.

### DETAILED DESCRIPTION OF THE PREFERRED EMBODIMENTS

Preferred embodiments of the invention provide a system and methods for determining the alignment of a substrate holder, such as a wafer boat, after the substrate holder is loaded and closed in a process chamber. A distance sensor is preferably attached to the substrate holder. The distance sensor can preferably be loaded and sealed within the process chamber along with the substrate holder. The sensor preferably senses a signal, e.g., light or sound generated by the sensor and reflected by the walls of the process chamber, which can vary depending on the distance of the walls from the sensor. In some preferred embodiments, the signal can be converted to a distance measurement, thereby allowing the sensor to measure the distance along a line between it and the walls of the process chamber. The direction of the line may be referred to as the measurement direction. The distance measurements can be communicated, e.g., wirelessly, to a device, e.g., a computer, outside of the process chamber to determine the alignment of the substrate holder. As discussed herein, the relationship between the measurement signals received by the sensor and angular position can be used to determine the presence of a misalignment. The signals can be converted to distance to determine the degree of the misalignment. For example, the relationship of distance with angular position can be fitted to theoretical models to quantify numerical parameters to describe the misalignment of the substrate holder. If a misalignment is present, the substrate holder or any structures supporting the substrate holder can be repositioned, e.g., using the numerical parameters as a guide, to correct the misalignment.

When performing measurements, the measurement direction is preferably perpendicular to the axis on which the substrate holder rotates. It will be appreciated that the centering of the substrate holder can be determined by measuring the distance between the distance sensor and the wall of the process chamber. The measurements are preferably taken coplanar with a cross-sectional slice of the process chamber.

The distance sensor, with or independently of the substrate holder, can be rotated. The distance between the distance sensor and the process chamber wall as a function of the angular position can be used to gauge the centering of the substrate holder. Thus, multiple distance measurements are preferably taken, with each measurement taken with the sensor rotated at a different angle relative to a previous measurement. Depending on the shape of the process chamber, a properly centered substrate holder will have a particular expected relationship between rotational angle and distance. For example, for a cylindrical process chamber, the distance between the distance sensor and the process chamber wall is typically constant as a function of rotational angle where the substrate holder is centered in the process chamber. Variations in distance typically indicate misaligned substrate holder.

It will be appreciated that the substrate holder can be misaligned in various ways. Three axes can be used to describe the alignment of the substrate: 1) the substrate holder rotation axis, which is the axis about which the substrate holder rotates; 2) the substrate holder axis, which runs through the center of the substrate holder and is preferably parallel to the rotation axis; and 3) the process chamber axis, which runs through the center of the process chamber and is also preferably parallel to the rotation axis. The rotation axis, substrate holder axis and process chamber axis preferably coincide when the substrate holder is centered. However, horizontal displacement or tilting of the substrate holder can cause misalignments of the rotation axis and/or substrate holder axis with each other and/or with the process chamber axis. Such misalignments are indicative of an off- center substrate holder.

Rotation of the distance sensor with or independently of the substrate holder can be used to determine the alignment of the rotation, substrate holder and process chamber axis. For example, the substrate holder can be held still and the sensor can be rotated, to determine the alignment of the substrate holder axis with the process chamber axis. In another set of measurements, the sensor can be held still relative to the substrate holder and the substrate holder can be rotated, to determine the alignment of the axis of rotation of the substrate holder relative to the process chamber axis.

In addition to misalignments of the substrate holder due to lateral shifts of the wafer boat, the substrate holder can be misaligned due to being tilted. To measure this type of misalignment, two or more sets of measurements, each at different heights, can be obtained. Preferably, two or more sensors at different heights are used, one to make each set of measurements. In some embodiments, a single sensor is used by making measurements at one height and then moving the sensor to make measurements at another height. For a given angle of rotation of either the boat or the sensor and locating the sensors at similar positions relative to the substrate holder axis, a tilted substrate holder will give different distance measurements, while a substantially vertical substrate holder will give substantially equal measurements.

Having determined the orientation of the substrate holder relative to the walls of the process chamber by determining the relative alignment of the rotation axis, the substrate holder axis and the process chamber axis, any undesirable orientations can be corrected before substrate processing commences.

Advantageously, by providing the measurement sensor on a substrate holder and allowing the measurement sensor to communicate with a device external to the process chamber, the alignment of the substrate holder in the process chamber can be measured after the substrate holder is loaded and sealed in the process chamber. Thus, more accurate determinations of the alignment of the substrate holder in the process chamber can be made. By more uniformly orienting the substrate holder relative to the process chamber, high quality process results, e.g., highly uniform deposited layers, can be achieved.

Reference will now be made to the Figures, wherein like numerals refer to like parts throughout.

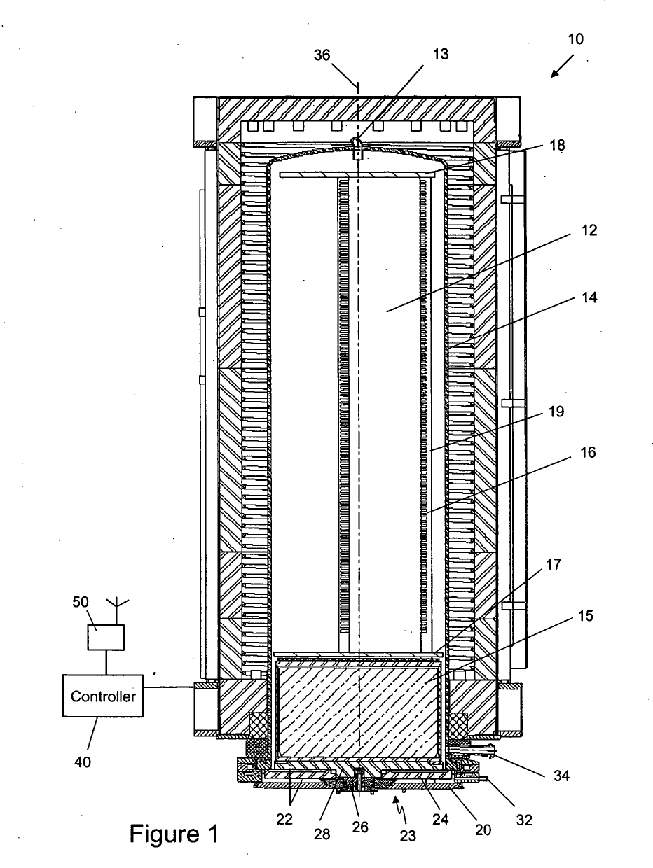

FIG. 1 illustrates an exemplary batch reactor, commercially available under the trade name A412™ from ASM International N.V. of Bilthoven, The Netherlands. The illustrated reactor is a vertical furnace type of reactor, which has benefits for efficient heating and loading sequences, but the skilled artisan will appreciate that the principles and advantages disclosed herein will also have application to other types of reactors.

With continued reference to FIG. 1, a reaction chamber 12 is delimited by a substantially cylindrical process tube 14 extending in a vertical direction. The process tube 14 has a central axis 36 which extends vertically through the center of the tube 14. When the tube is perfectly cylindrical and straight, the axis 36 preferably extends through the centers of horizontal cross-sections of the tube 14. The lower end of the tube 14 is open and can be closed with a door construction 23 comprising a metal door 20 and a quartz door 24. The door construction 23 supports a pedestal 15, which in turn supports a wafer boat 16. The boat 16 comprises a lower end plate 17 and an upper end plate 18 connecting three boat rods 19 having recesses that form accommodations for wafers (not shown). The wafers, after loading into the boat 16, are each held horizontally, in a vertically stacked and spaced manner. Process gas enters the reaction chamber 12 via a process gas inlet 13 proximate the top of the reaction chamber 12 and typically flows downward to exit the reaction chamber 12 via a gas exhaust 34 proximate the bottom of the reaction chamber 12.

In the illustrated embodiment, the door construction 23 is provided with a boat rotation bearing 26 that is configured to couple with a boat rotation driving motor (not shown). During processing, the boat rotation bearing 26 can rotate the boat 16 by rotating the boat pedestal 15 supported on the door 23. In the illustrated reactor 10, the boat rotation bearing 26 supports a rotating plate 28, which directly contacts and supports the pedestal 15.

During processing an inert gas volume 22 can be maintained at the lower end of the reaction chamber 12 by flowing inert gas or “purging” gas from a gas inlet 32. The inert gas volume 22 has a pressure slightly higher than the pressure inside the reaction chamber 12, so that a positive flow of inert gas into the reaction chamber 12 is always maintained. Such a purge scheme is discussed in U.S. application Ser. No. 11/038,357, filed Jan. 18, 2005, the entire disclosure of which is incorporated herein by reference.

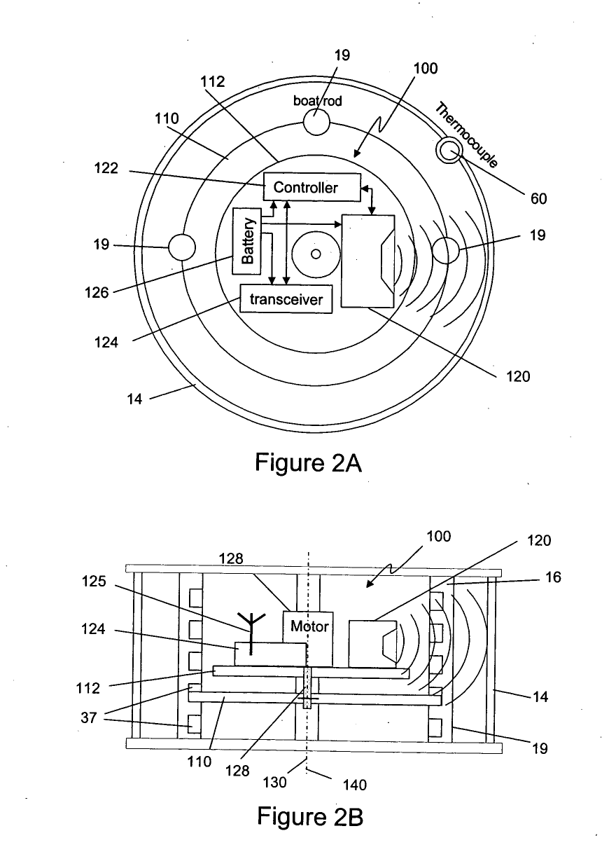

A controller 40 controls various process parameters of the reactor 10. The controller 40 can be provided with a transceiver 50, for wireless communication with a sensor system 100 (FIGS. 2A and 2B) in the process chamber 12.

FIGS. 2A and 2B show the sensor system 100, formed in accordance with preferred embodiments of the invention. A sensor holder 110, which is a base plate in the illustrated embodiment, is secured in, or mounted on, an accommodation formed by recesses 37 in boat rods 19 of the wafer boat 16. A sensor plate 112 is rotatably mounted to the base plate 110. The sensor plate 112 has an axis of rotation 130. Preferably, the base plate 110 is positioned such that the sensor rotation axis 130 coincides with the desired center of a wafer, when the wafer is accommodated and centered in the recesses 19 of the wafer boat 16. When properly positioned, the axis 130 preferably coincides with the axis of the wafer boat 16 (FIG. 1). The wafer boat 16 also has an axis 140 on which it rotates. The boat rotation axis 140 preferably coincides with the boat axis (which coincides with the sensor rotation axis 130, when the sensor system 100 is properly loaded into the wafer boat 16) and the process chamber axis 36. Also, the sensor rotation axis 130 is preferably perpendicular to a plane on which a major face of the wafer extends. Where the substrates are semiconductor wafers, the base plate 110 is preferably circular, and the sensor rotation axis 130 preferably extends through the center of the base plate 110. More preferably, the base plate 110 has roughly the same shape and size as substrates accommodated in the wafer boat 16. Thus, the sensor system 100 can be secured, like a wafer, in the wafer boat 16 in the already present recesses 37, thereby advantageously allowing measurements to be made without having to modify the wafer boat 16 to accommodate the measurement system 100.

With continued reference to FIGS. 2A and 2B, a rotation motor 128 is configured to rotate the sensor plate 112 relative to the base plate 110. A distance sensor 120 is mounted on the sensor plate 112 and is preferably configured to sense a signal related to distance and, preferably, to measure, using the signal, the distance between the sensor 120 and the nearest obstacle in the viewing window of the sensor 120. Preferably, the viewing window is directed parallel to the wafer accommodation plane, and in a radial direction. The sensor plate 112 is further provided with a controller unit 122, a transceiver 124, an antenna 125 and a battery 126. The sensor 120, the controller unit 122 and the transceiver 124 are connected to the battery 126. The sensor 120 and the transceiver 124 are connected to and controlled by the controller 122. The transceiver 124 is connected to the antenna 125. Through the transceiver 124 and the antenna 125, signals can be transmitted and received wirelessly to and from the transceiver 50 (FIG. 1), located outside the process tube 14 (FIG. 1). The second transceiver 50 is connected to an operator station, comprising the controller 40, which comprises a control unit and a user interface for viewing data and entering commands. In the example shown, the sensor 120 is an ultrasound range sensor which provides a signal that corresponds to the distance between the sensor 120 and any obstacle nearest the sensor 120.

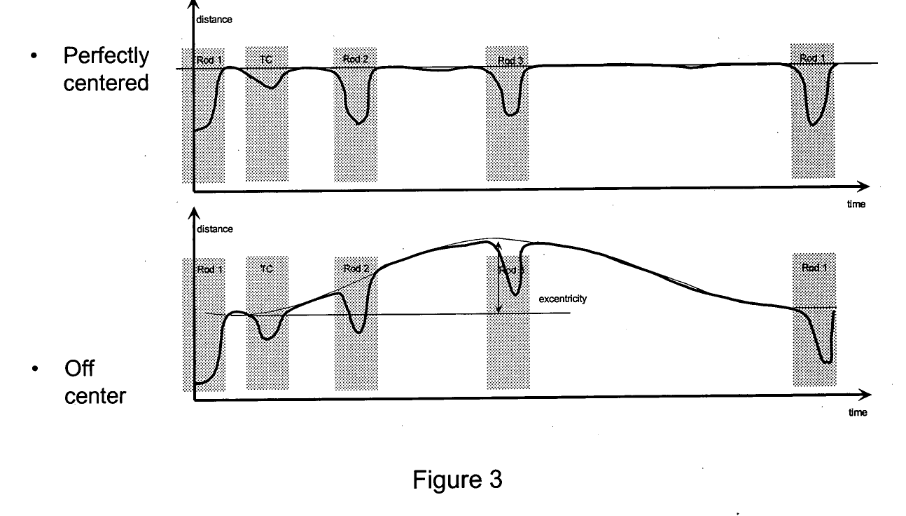

With reference to FIG. 3, the alignment of the wafer boat 16 can be determined by measuring the distance between the sensor 120 and the process tube walls 14 (FIGS. 2A and 2B) as a function of time in a period during which the sensor plate 120 is rotated. By rotating the sensor plate 112 and continuously recording the distance measured by the sensor 120, graphs such as that schematically presented in FIG. 3 can be obtained. The upper graph of FIG. 3 shows the graph expected from a boat 16 (FIGS. 1 and 2A-2B) which is substantially centered in the process tube 14. It will be appreciated that local variations in distance are observed, due to the presence of localized obstacles, such as the boat rods 19 (FIGS. 2A-2B) and any protrusions in the process tube 14, such as a shaft to accommodate a thermocouple 60 (FIG. 2A and represented as TC in the graphs of FIG. 3). Filtering out these local variations, as indicated by the shaded parts of the graphs of FIG. 3, the measured distance during one rotation is substantially constant, indicating that the sensor rotation axis 130 substantially coincides with the process chamber axis 36.

The bottom graph of FIG. 3 shows a situation in which the sensor rotation axis 130 does not coincide with the process chamber axis 36. With reference to the bottom graph, the measured distance varies between a maximum and a minimum value during one rotation, even when the variations due to local obstacles, e.g., the thermocouple 60 and the three rods 19 of the wafer boat 16 (FIG. 2A), are filtered out. The variation in distance indicates that the sensor rotation axis 130 does not coincide with the process chamber axis 36. After filtering out the disturbances due to local obstacles, the curve has a roughly sinusoidal shape: during half a rotation, the measured distance is above an average value and during the other half of the rotation the measured distance is below the average value.

It will be appreciated that, for optimal functioning of the vertical furnace 10, the wafer boat 16 is preferably centered relative to the process tube 14 not only in a static mode, but also when the boat 16 is rotated. In other words, the axis of boat rotation 140 is preferably centered relative to the process tube 14, i.e., the boat rotation axis 140 is coincident with the process chamber axis 36. As a first step in testing the alignment, a test can be done with the boat rotation switched on and with the sensor plate 112 stationary relative to the base plate 110, and therefore rotating with the boat 16. This will reveal if the axis of boat rotation 140 is centered relative to the process tube 14. Then a test can be done with the boat 16 stationary and the sensor plate 112 rotating relative to the base plate 110. This will reveal if the sensor rotation axis 130 is centered relative to the process tube. Assuming that the sensor system 100 is properly loaded into the wafer boat 16, i.e., that the sensor rotation axis 130 coincides with the central axis of the wafer boat 16, this test will also reveal if the wafer boat 16 is centered relative to the process tube 14.

It will be appreciated that distance measurements can be taken continuously as the sensor 120 is rotated or can be taken at particular points during the rotation of the sensor 120. Preferably, at least three measurements are taken at different rotational orientations of the sensor 120. More preferably, the orientations equally divide the 360 degrees of a complete rotation. For example, where three measurements are taken, the measurements are preferably taken at orientations that are rotated about 120° relative to each other. Where measurements are taken at particular points, however, care is preferably taken, by orienting the sensor 120 before any measurements and/or by the selection of measurement points, so that the distance to the walls of the process chamber 12 is measured and not the distance to obstacles, such as the wafer boat rods 19 between the sensor 120 and the process tube 14.

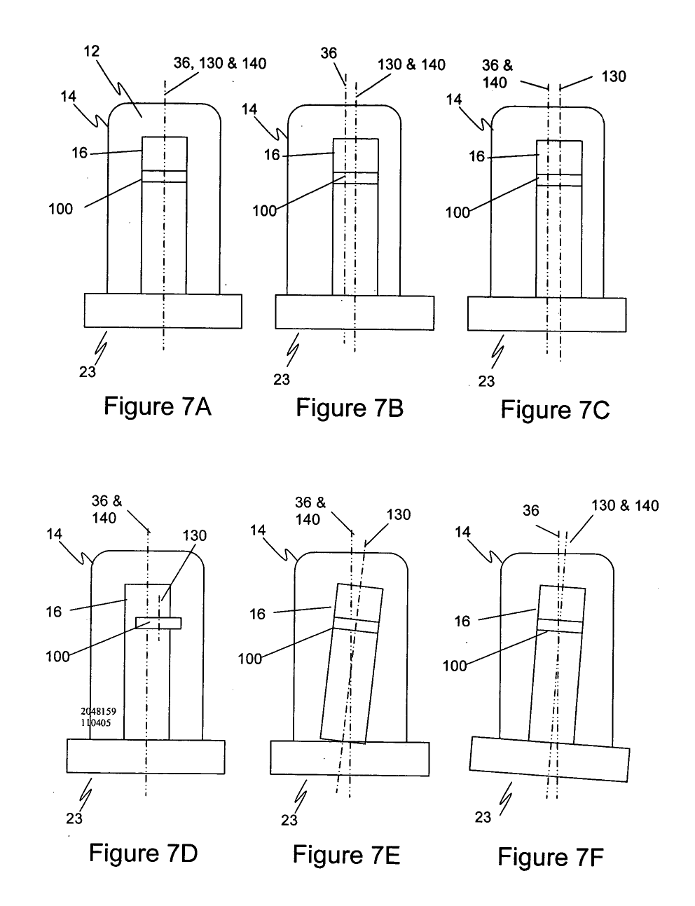

Advantageously, a measurement with sensor 120 at three or more angular orientations can verify the centering of the wafer boat 16 with respect to the process tube 14 at the height where the measurement is taken. However, there can also be a misalignment between the vertical axes of the wafer boat 16 and the process tube 14, e.g., the wafer boat 16 may be tilted relative to the process tube 14. The occurrence of tilting can be investigated by performing at least two sets of measurements with the base plate 110 received in wafer accommodations at different heights in wafer boat 16, as discussed below with reference to FIGS. 7A-7F. For example, one measurement set can be taken at a lower end and another measurement set taken at an upper end of wafer boat 16.

It will be appreciated that the sensor 120 can be various devices known in the art used for measuring distance. The sensor 120 preferably emits a signal and senses the reflection of the signal, which varies in a known way with the distance of an object which caused the reflection. Any variations in the reflected signal with angular position can be used to determine the presence of misalignments. In some embodiments, the reflected signals can be converted to numerical distance values to quantify the degree of misalignment, as discussed below with reference to FIG. 7.

The sensor 120 can be an ultrasound range sensor, which allows contactless distance measurments. Such a sensor emits pulses of ultrasound and senses the ultrasound pulses that are reflected by an object in front of it, such as the process tube 14. The distance from the sensor to the object is derived from the time delay between the emitted pulses and the received, reflected pulses. Other sensors and measurement techniques can also be applied. For example, distance sensors (or displacement sensors or range sensors) available for use in robotics or in automotive applications are also suitable.

Also, instead of ultrasound, electromagnetic radiation, such as optical radiation, can be emitted and/or sensed by the sensor to gauge distance. Such an optical range sensor can emit optical radiation such as infrared light, visible light or ultra violet radiation.

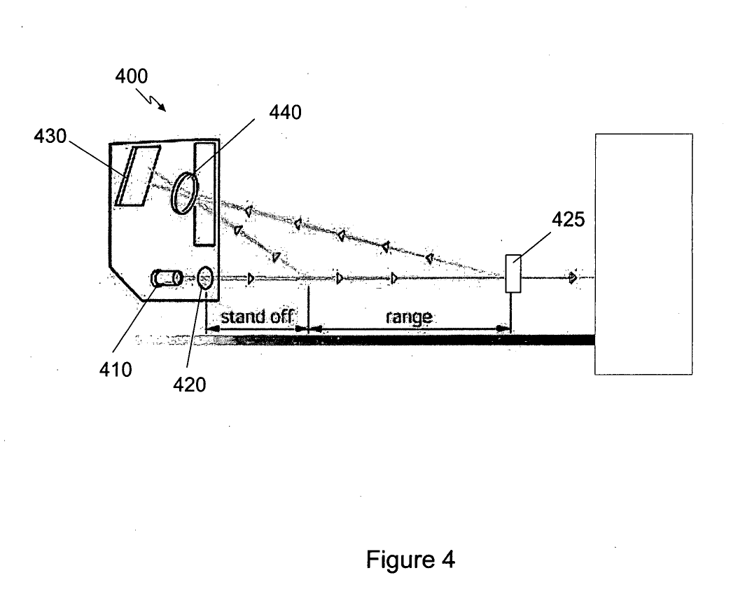

In some embodiments, optical range sensors using laser beams can be applied. Instead of the echo technique typically applied by ultrasound sensors, interferometry or triangulation methods can be applied to gauge distance with laser sensors. Such a triangulation method is explained with reference to FIG. 4. The triangulation sensor is referred to in its entirety by 400. A small bright beam of light is emitted by a laser 410 through an output window 420. When the beam hits an object 425, the light is scattered and reflected. A receiver is positioned at a distance away from the laser and comprises an aperture 440, comprising a lens, and a light detector 430, comprising, for example, a linear array of photodiodes. For faster response, a Position Sensitive Detector can be used instead of the array of photodiodes. It will be appreciated that what is actually measured is the angle at which the scattered or reflected light is observed. The measured angle is converted into a distance by trigonometric calculations. The viewing angle is limited, which may limit the distances that can be measured in a certain range.

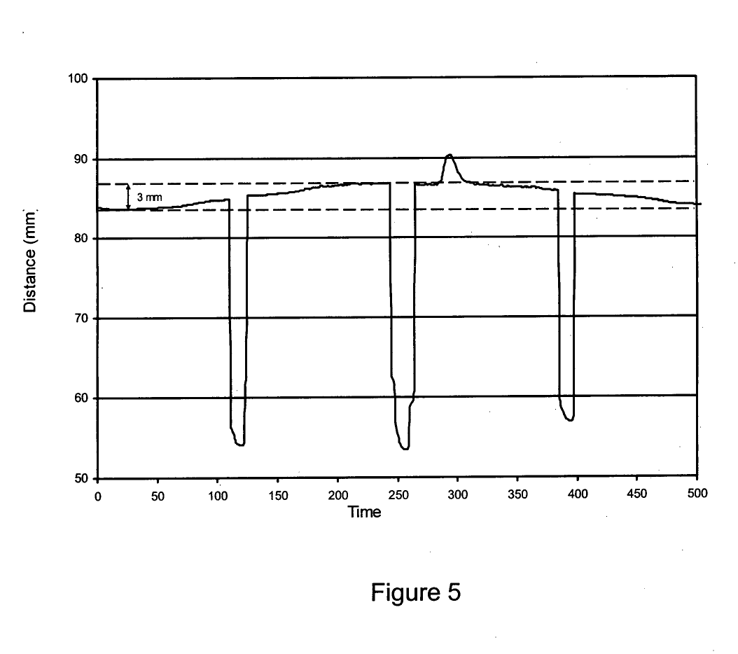

With reference to FIG. 5, a graph is shown plotting the curve derived from an actual set of measurements performed in the process chamber of an A412™ reactor from ASM International N.V. of Bilthoven, The Netherlands. The boat rods can be recognized as pronounced dips in the curve and the thermocouple shaft is perceivable as a small peak. In this example, the boat is not centered. The difference between minimum and maximum distance, ignoring the variations likely due to the boat rods and thermocouple shaft, is about 3 mm. This indicates that the boat is about 1.5 mm off center. In this figure, the horizontal axis is divided in units of time. Because the rotation speed was constant, each unit of time corresponds to a particular angular position. In other preferred embodiments, the angular orientation can be directly measured and recorded.

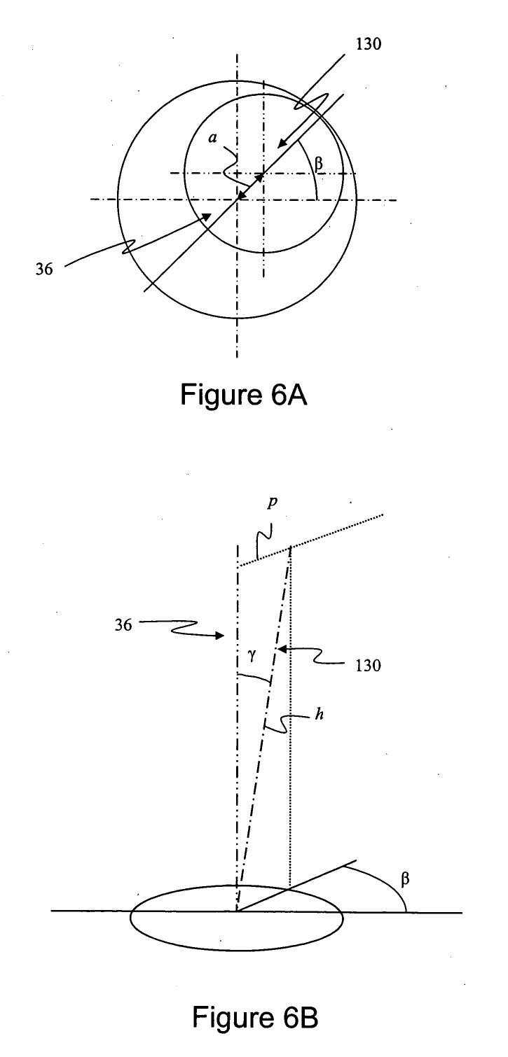

Without limiting the invention by theory, the principles pertaining to measuring the alignment of the wafer boat 16 will now be discussed in more detail from a theoretical point of view. In FIG. 6A, an off-center situation is represented schematically. The measuring device rotation axis 130 is shifted over a distance a relative to the process chamber axis 36, in a direction defined by an angle β in the horizontal plane. In FIG. 6B a non-parallel alignment of the measuring device rotation axis 130 and the process chamber axis 36 is represented schematically. The measuring device rotation axis 130 is tilted over an angle γ in a direction defined by the angle β in the horizontal plane. The wafer boat into which the measuring device is loaded has a height h and, at the top of the wafer boat, the measuring device rotation axis 130 is displaced from the process chamber axis 36 by a distance p. These variables can be used to quantify the degree of misalignment of the wafer boat 16, as discussed below with respect of FIGS. 7A-7F.

Misalignments of a substrate holder can be caused by various factors. For example, the door 23 that supports the wafer boat 16 can be laterally shifted and/or closed at a slant relative to an idealized orientation of the door 23 (FIG. 1) in a closed position. This misalignment of the door 23 can cause a misalignment of the wafer boat 16 and, consequently, a misalignment of the wafer boat rotation axis 140. In addition, the wafer boat 16 may be shifted or may rest at a tilt after being placed on the door plate 23, resulting in a misalignment of the rotation axis 130 of a measuring system 100 that is positioned in the wafer boat 16. Finally, the measuring system 100 itself can be placed incorrectly in the boat 16, resulting in measurements which indicate an incorrectly positioned boat 16. In practice, any combination of these and other situations can occur.

A number of different situations are represented schematically in FIGS. 7A-7F and described below. As in FIG. 1, the wafer boat 16 inside the process tube 14 is supported on the door 23. The measuring system 100 is loaded in the wafer boat 16. The process tube 14 defines the process chamber 12, which has the process chamber axis 36. The measuring system 100 has the measuring system rotation axis 130 and the wafer boat 16 rotates on the wafer boat rotation axis 140. It will be appreciated that misalignments of the various axis 36, 130, 140 can be the result of the misalignments any of the following with each other: the wafer boat 16, the door 23, the process tube 14, the measuring system 100 and any structures that may intervene between the wafer boat 16 and the door 23.

Various alignment scenarios are shown in FIGS. 7A-7F, as follows:
FIG. 7A: The wafer boat 16 is substantially centered in the process tube 14 and on the door 23, which is correctly aligned with the process tube 14. The measuring system rotation axis 130, boat rotation axis 140 and process chamber axis 36 coincide.
FIG. 7B: The measuring system rotation axis 130 and boat rotation axis 140 coincide, but are shifted (by a distance α at an angle β in the horizontal plane) relative to the process chamber axis 36. This could indicate that, e.g., the wafer boat 16 is correctly aligned with the door plate 23, but the door plate 23 is incorrectly aligned due to being shifted laterally.
FIG. 7C: The boat rotation axis 140 coincides with the process chamber axis 36. The measuring system rotation axis 130 is parallel to but shifted (by a distance α at an angle β in the horizontal plane) relative to the process chamber axis 36. This could indicate that, e.g., the wafer boat 16 is incorrectly aligned with a correctly aligned door plate 23.
FIG. 7D: The boat rotation axis 140 and process chamber axis 36 coincide, but the measuring system 100 itself is not centered in the boat 16 (the measuring system 100 is displaced by a distance α at an angle β in the horizontal plane). This could indicate that the measurement system 100 is incorrectly loaded into the boat 16 and may need to be repositioned.
FIG. 7E: The boat rotation axis 140 and the process chamber axis 36 coincide, but that measuring system rotation axis 130 is tilted relative to the process chamber axis 36 (being tilted an angle γ relative to the process chamber axis 36 and in the direction of the angle β in the horizontal plane). This could indicate that, e.g., the door plate 23 is correctly aligned, but the wafer boat 16 is incorrectly aligned with the door plate 23.
FIG. 7F: The boat rotation axis 140 and the measuring system rotation axis 130 coincide, but the boat rotation axis 140 is tilted relative to the process chamber axis 36 (being tilted an angle γ relative to the process chamber axis 36 and in the direction of the angle β in the horizontal plane). This could indicate that the wafer boat 16 is corrected aligned on the door plate 23, but the door plate 23 is misaligned with the process tube 14.

In another deviation from an idealized wafer boat orientation, not illustrated in FIG. 7, the tube 14 defining the process chamber 12 may not be perfectly cylindrical in shape. To account for such variations, as a first step in interpreting and/or plotting the measurements, the dimension data of the tube 14 is preferably subtracted and/or added to the measured data, as appropriate. For example, the distance of the tube 14 from a selected center point is preferably known for each angular orientation of the sensor 120 (FIGS. 2A-2B) and this distance can be averaged. Values above this average can be subtracted from corresponding measurements made by the sensor 120 and values below this average can be added to the measurements. In other embodiments, no compensation for a non-uniform process tube shape is made; rather, the measurements are taken and the wafer boat 16 is positioned, as closely as possible, in the idealized center of the process chamber 12, given the non-uniform tube shape.

As noted above, to determine deviations from a perfectly centered alignment, four different sets of distance measurements are preferably taken. To determine lateral shifts relative to the process chamber axis 36 at a given height in the boat 16, a first measurement is preferably performed while rotating the boat 16 by means of the boat rotation mechanism (BR) (so that the sensor 120 is rotated with the boat 16) and a second measurement is preferably performed while rotating the sensor 120 by means of a rotation of the sensor turntable (TT) 112 while the boat 16 is stationary. To determine tilts of the measurement system rotation axis 130 and of the boat rotation axis 140 relative to the process chamber axis 36, each of the previously described measurements are preferably performed with the measuring system 100 positioned at two different heights, h₁ and h₂, in the boat 16.

It will be appreciated that the various axis 36, 130, 140 are laterally shifted by varying amounts, as determined by sensor measurements, relative to one another if the boat 16 is tilted. Thus, sensor measurements that vary with the height of the measuring system 100 in the boat 16 indicate that the boat 16 is tilted, as illustrated in FIGS. 7E or 7F. To differentiate between the scenarios of FIGS. 7E and 7F, the variation in measurements with rotation of the BR and the TT are investigated. If the distance measurements vary with the measuring angle α of both the BR and the TT, then the boat rotation axis 140 is itself tilted relative to the process chamber axis 36 (FIG. 7F). If the lateral axis shifts vary with height according to measurements with the TT, but not with the BR, then the boat rotation axis 140 is aligned with the process chamber axis 36 but the measurement system rotation axis 130 and, hence, the wafer boat axis, is misaligned (FIG. 7E).

If the distance measurements do not vary as a function of the height of the measurement device in the boat, then the situation of one of FIGS. 7A, 7B, 7C or 7D may exist. The situation of FIG. 7A exists if the distance measurements do not vary as a function of the measuring angle of the BR and the TT. The situation of FIG. 7B exists if the distance measurements vary both with the measuring angle of the BR and the TT. The situation of one of FIGS. 7C or 7D exists if the distance measurements vary with the TT rotation angle but does not vary with the BR rotation angle. The situations of FIGS. 7C and 7D can be differentiated when the rods 19 of the boat 16 are within measuring range of the sensor 120. In FIG. 7C, the rotational axis 130 of the sensor 120 is centered within the boat 16 and the measured distances between the rods 19 and the sensor 120 are substantially equal. In FIG. 7D, the rotational axis 130 of the sensor 120 is off-center in the wafer boat 16 and the measured distances between the rods 19 and the sensor 120 vary. If the rods 19 of the boat 16 are not within measuring range of the sensor 120, care is preferably taken to ensure that the measuring system 100 is centered in the boat 16.

Having determined qualitatively the type of misalignment present, this information can be used as a guide for the type of corrective action desired. For example, if the situation of scenario B is found, attention can be directed to repositioning the door 23. In another example, if the situation of scenario C is present, then attention can be focused on repositioning the boat 16 relative to the door plate 23.

More preferably, in addition to determining in a binary fashion whether a wafer boat 16 is properly aligned or not, the measured data can also be used to quantify various parameters of any misalignment, to advantageously better guide any corrective action. To do so, the distance measurements, as a function of measuring angle or rotation angle α, that is expected for a given off-center distance α, horizontal angle β and tilt angle γ, can be modeled using trigonometric functions. Experimental data obtained from an actual set of measurements can then be fitted to the trigonometric functions to obtain estimated values for α, β and γ. The qualitative misalignment information can be used to focus the set of models looked at, e.g., to determine whether one of the models of scenarios A-F apply, or the experimental data can simply be compared to all of the models to find a match. Once a match is found, the values used to generate the model can serve as the estimated values for α, β and γ used to describe the misalignment.

Below, the distance or signal sensed by the sensor, S(α), as a function of rotation angle α of the turntable (TT) is represented by a trigonometric function for the different situations B to F. It will be appreciated that the signal received by the sensor is related to the distance between the sensor and an object reflecting the signal. This signal can be converted, if desired, into a distance measurement.

The letters B-F below refer, respectively, to the situations represented in FIGS. 7B-7F. In the formulas, as noted above, α is the lateral shift from the center, the angle β defines the direction of the shift, the angle γ is the tilt of the wafer boat rotation axis relative to the process chamber or process tube axis and R is the radius of the process tube.

$$B \text{:}$$

$${S}_{TT} ( α ) = a \cdot cos ( 90 + β - α ) + \sqrt{- {a}^{2} + {R}^{2 +} {a}^{2} \cdot {cos}^{2} ( 90 + β - α )}$$

$${{S}_{BR} ( α )}_{{h}_{1}} = {{S}_{BR} ( α )}_{{h}_{2}} = {{S}_{TT} ( α )}_{{h}_{1}} = {{S}_{TT} ( α )}_{{h}_{2}}$$

In scenario B, the signal varies with the measuring angle α and is equal for rotation of the boat (BR) and rotation of the turntable (TT). Because all axes 36, 130, 140 are parallel, identical signals will be measured at any given angular position a with the sensing device at different heights h₁ and h₂ in the boat.

$$C \text{:}$$

$${S}_{TT} ( α ) = a \cdot cos ( 90 + β - α ) + \sqrt{- {a}^{2} + {R}^{2} + {a}^{2} \cdot {cos}^{2} ( 90 + β - α )}$$

$${S}_{BR} ( α ) = a \cdot cos ( 90 + α ) + \sqrt{- {a}^{2} + {R}^{2} + {a}^{2} \cdot {cos}^{2} ( 90 + α )} \\ {{S}_{TT} ( α )}_{{h}_{1}} = {{S}_{TT} ( α )}_{{h}_{2}} {{S}_{BR} ( α )}_{{h}_{1}} = {{S}_{BR} ( α )}_{{h}_{2}}$$

In scenario C, where the sensor is offset due to a misaligned boat, S_{TT}(α) varies with the measuring angle α, but, for a boat rotation mechanism properly aligned with the process chamber, S_{BR}(α) does not vary with α. Because the process chamber and wafer boat rotation axes 36, 140 are aligned, identical distances apply with the sensing system 100 at different heights h₁ and h₂ in the boat 16.
D: In scenario D, because the relative alignments of the process chamber axis 36, the wafer boat rotation axis 140 and the measurement system rotation axis 130 are the same, this scenario has the same relationships between variables as scenario C.

$$E \text{:}$$

$${S}_{TT} ( α , h ) = p \cdot cos ( 90 + β - α ) + \sqrt{- {p}^{2} + {R}^{2} + {p}^{2} \cdot {cos}^{2} ( 90 + β - α )}$$

$${S}_{BR} ( α , h ) = p \cdot cos ( 90 + β ) + \sqrt{- {p}^{2} + {R}^{2} + {p}^{2} \cdot {cos}^{2} ( 90 + β )}$$

$$wherein p = h \cdot sin γ$$

In scenario E, because the wafer boat 16 is tilted, both S_{TT}(α,h) and S_{BR}(α,h) vary as a function of the height h. Because the boat rotation axis 140 coincides with the tube axis 36, S_{BR}(α,h) does not vary with α. Because the measuring system rotation axis 130 does not coincide with the tube axis 36, however, S_{TT}(α,h) does vary with α. Theoretically, S_{TT}(α,h) and S_{BR}(α,h) are multiplied by

$$1 - ( sin ( β - α ) \cdot ( 1 ( \frac{1}{cos γ} ) ) ) .$$

However, the value of this multiplier is close to 1 and the multiplication can be neglected in most cases.

$$F \text{:}$$

$${S}_{TT} ( α , h ) = p \cdot cos ( 90 + β - α ) + \sqrt{- {p}^{2} + {R}^{2} + {p}^{2} \cdot {cos}^{2} ( 90 + β - α )}$$

$$wherein p = h \cdot sin γ$$

$${S}_{TT} ( α , h ) = {S}_{BR} ( α , h )$$

In scenario F, because the wafer boat 16 is tilted, both S_{TT}(α,h) and S_{BR}(α,h) vary as a function of the height h. Because the boat and measuring system rotation axis 130, 140 coincide, identical distances apply for rotation of the sensor turntable (TT) and for the boat rotation mechanism (BR). Again, theoretically, S_{TT}(α,h) and S_{BR}(α,h) are multiplied by

$$1 - ( sin ( β - α ) \cdot ( 1 ( \frac{1}{cos γ} ) ) ) ,$$

but this is multiplier is close to 1 and can be neglected.

Thus, using the measurement system discussed herein, substrate holder misalignments can be detected and corrective action can be taken. The type of substrate holder misalignment (e.g., as represented in FIGS. 7A-7B), if any, can be qualitatively determined by taking distance measurements at two or more heights in the substrate holder. The parameters of the misalignment can be quantified by fitting the measured data with various theoretical models. Having determined the misalignment present, the substrate holder, or door construction or other intervening structures (e.g., pedestals), if present, can be repositioned to correct the misalignment.

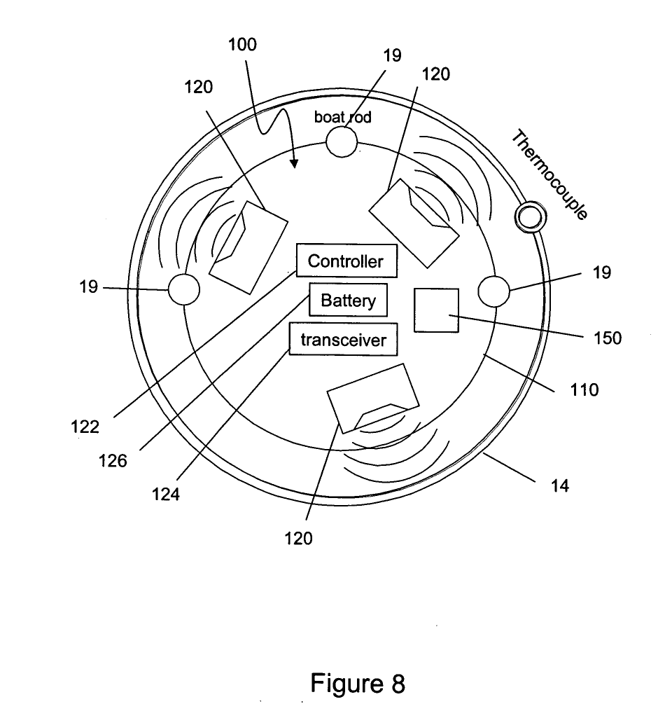

It will be appreciated that various modifications can be made to the illustrated embodiments. For example, rather than rotating a single distance sensor, multiple sensors, e.g., three or more sensors pointing in three or more directions, can be used to measure the distance to the process chamber wall. In that case, the rotation axis and drive motor can be omitted and the measuring system advantageously becomes simpler. Such a measuring system is shown in FIG. 8, wherein like reference numerals refer to like parts shown in FIG. 2. Three sensors 120 are mounted on the sensor holder 110, the sensors oriented in directions about 120° apart. The sensor system 100 should be positioned in the wafer boat 16 such that the sensors are directed to parts of the process tube 14 without any obstructions, which can include boat rods 19 or shafts for the thermocouple 60. It will be appreciated that, in FIG. 8, the the sensors 120, the controller 122, the battery 126 and and the transceiver 124 are electrically connected. The sensors 120 can be various types of sensors, as noted above. In some embodiments, the sensors 120 are ultrasonic sensors, which are advantageously inexpensive and compact. For example, sensors available from PIL Sensoren GmbH, Hainstrasse 50 D-63526 Erlensee, Germany, model P43-K4U-2G-1C0-400E, are suitable. Advantageously, such sensors provide a suitable measuring distance range of about 25-250 mm and have compact dimensions of 12×26×40 mm.

In some embodiments, the distance sensors as proposed herein can be combined with an electronic level device or sensor 150 (FIG. 8). Any tilt of the wafer boat or of the boat rotation axis can be detected by the level device 150, so that the distance measurements as described herein can be performed at only one height in the boat.

It will be appreciated that various other modifications can be made to the illustrated embodiments. For example, while the sensor system and outside controllers are preferably each provided with a transceiver and antenna for wireless, real time communication with each other, in some embodiments, the sensor system and outside controllers are provided without such a wireless communication system. Rather, the sensor system can store measured data, which is downloaded via a wire connected to a processing unit for analysis after the sensor system is removed from the process chamber. In other arrangements, the stored data can be downloaded in real time via a wire through a universal joint. In addition, rather than being controlled wirelessly during a measurement, the sensor system can function according to a pre-programmed routine after being loaded into the process chamber.

In addition, while the sensor system is preferably provided, for ease of implementation, on a base plate which allows it to be accommodated in a preexisting slot in a substrate holder, the sensor system can be attached to any part of the substrate holder. For example, the sensor system can be secured, e.g., via clamping, on another part of the substrate holder, e.g., the rods of the substrate holder. In such cases, the sensor system is preferably configured such that the axis of rotation of the sensor coincides with the substrate holder axis.

While the axis of rotation of the sensor, whether accommodated in a substrate slot or not, preferably coincides with the axis of the substrate holder, it will be appreciated that the axis of rotation of the sensor may not coincide with the axis of rotation of the substrate holder in some cases (e.g., FIG. 7D). In such cases, the measured data from the sensor is preferably adjusted, e.g., by the addition or subtraction of values, to account for expected increases and/or decreases in the measured distances as a sensor rotates.

Also, while discussed above with respect to measuring distance for ease of discussion and illustration, it will be appreciated that the signal sensed by the distance sensor varies with distance and, in some embodiments, the signal is not converted to distance; rather, the variation of the signal with angular position can itself be used to gauge the alignment of the substrate holder. In other embodiments, the signal is converted to distance, to advantageously allow the degree of misalignment, if any, to be quantified.

The sensor system can advantageously be used to measure the alignment of the substrate holder as part of a maintenance procedure, to calibrate the alignment of the substrate holder before processing a batch of substrates, although the sensor system can be used at other times as desired. It will be appreciated that the substrate holder can be otherwise empty during the measurement or the other available substrate accommodations can be filled with substrates or dummy substrates to better simulate the weight load experienced by the substrate holder and any rotation systems during processing.

Accordingly, it will be appreciated by those skilled in the art that various other omissions, additions and modifications may be made to the methods and structures described above without departing from the scope of the invention. All such modifications and changes are intended to fall within the scope of the invention, as defined by the appended claims.

1. A semiconductor processing system, comprising:
a vertical batch furnace having a process chamber;
a wafer boat configured to be accommodated in the process chamber, the wafer boat comprising a plurality of wafer slots for accommodating semiconductor wafers; and
a distance measurement system comprising:
a base plate sized and shaped to be accommodated in a wafer accommodation; and
a distance sensor attached to the base plate.

2. The semiconductor processing system of claim 1, wherein the measurement system comprises three or more distance sensors configured to measure distance in three or more different directions.

3. The semiconductor processing system of claim 1, wherein the distance measurement system further comprises a level sensor configured to detect any tilt of the wafer boat.

4. The semiconductor processing system of claim 1, wherein the distance sensor is controllably rotatable.

5. The semiconductor processing system of claim 1, wherein the distance sensor is configured to measure distance in a direction substantially parallel to the base plate.

6. The semiconductor processing system of claim 1, wherein the wafer boat comprises a plurality of rods, each rod having a plurality of support surfaces defining the plurality of wafer accommodations.

7. The semiconductor processing system of claim 6, wherein the support surfaces are defined by recesses in the rods.

8. The semiconductor processing system of claim 1, wherein the process chamber is delimited by a cylindrical process tube.

9. The semiconductor processing system of claim 1, wherein the furnace further comprises a door construction at a lower end of the furnace, the door construction configured to support the wafer boat.

10. The semiconductor processing system of claim 9, wherein the door construction comprises a rotation bearing configured to rotate the wafer boat.

11. The semiconductor processing system of claim 9, further comprising a pedestal configured to rest upon the door construction and to directly support the wafer boat.

12. The semiconductor processing system of claim 1, wherein the distance sensor is mounted on a sensor plate which is mounted and rotatable relative to the base plate.

13. The semiconductor processing system of claim 1, further comprising a controller configured to convert distance sensor signals to numerical distance values.

14. The semiconductor processing system of claim 1, wherein the distance measurement system further comprises a transceiver and wherein the processing system further comprises an other transceiver outside the process chamber, the transceiver and the other transceiver configured with wireless communication with each other.

15. A sensor system for measuring the alignment of a substrate holder in a process chamber of a semiconductor processing batch reactor, comprising:
a sensor base configured to mount on the substrate holder;
a distance sensor rotatably mounted to the sensor base, the distance sensor configured to sense a signal indicative of distance between a wall of the process chamber and the sensor; and
a motor configured to rotate the sensor.

16. The sensor system of claim 15, wherein the sensor base is sized and shaped to be accommodated in a substrate accommodation in the substrate holder.

17. The sensor system of claim 16, wherein an axis of rotation of the distance sensor, when the sensor base is mounted on the substrate holder, extends through a desired center of a substrate, when the substrate is received in the substrate holder, and is oriented perpendicular to a desired orientation for a substrate accommodated in the substrate accommodation.

18. The sensor system of claim 15, further comprising a transceiver and an antenna attached to the sensor base, the transceiver and antenna configured to wirelessly communicate data to a second transceiver disposed outside the process chamber.

19. The sensor system of claim 15, further comprising a sensor controller attached to the sensor base.

20. The sensor system of claim 15, further comprising a power source attached to the sensor base, wherein the power source is configured to deliver power to the sensor and the motor.

21. The sensor system of claim 20, wherein the power source is a battery.

22. The sensor system of claim 15, wherein the distance sensor is an ultrasound range sensor.

23. The sensor system of claim 15, wherein the distance sensor is an optical range sensor.

24. A sensor system for determining the alignment of a substrate holder in a semiconductor batch process chamber, comprising:
a base plate sized and shaped to be accommodated in a substrate accommodation of the substrate holder; and
a distance sensor mounted to the base plate.

25. The sensor system of claim 24, wherein the substrate holder is a wafer boat.

26. The sensor system of claim 24, wherein the distance sensor is an ultrasound distance sensor.

27-54. (canceled)

55. A sensor system for measuring the alignment of a substrate holder in a process chamber of a semiconductor processing batch reactor, comprising:
a sensor base configured to mount on the substrate holder;
at least one distance sensor mounted to the sensor base, the distance sensor configured to sense a signal indicative of distance between a wall of the process chamber and the sensor,
wherein the sensor system is configured to sense the signal indicative of distance in at least three different directions, the directions distributed in a plane.

56. The sensor system of claim 55, wherein the directions are regularly distributed in the plane.

57. The sensor system of claim 55, wherein the at least one distance sensor comprises three or more distance sensors.

58. The sensor system of claim 57, wherein the three or more distance sensors are jointly configured to measure distance in each of the at least three different directions.

59. The sensor system of claim 55, wherein the at least one distance sensor is configured to rotate to measure distance in each of the at least three different directions.

60. The sensor system of claim 55, further comprising a level sensor configured to detect any tilt of the substrate holder.
